(19) United States
(12) Patent Application Publication
(10) Pub. No.: US 2026/0327457 A1
(43) Pub. Date: Oct. 22, 2026

(54) POLISHING SLURRY AND METHOD OF MANUFACTURING SEMICONDUCTOR DEVICE

(71) Applicant: SAMSUNG ELECTRONICS CO., LTD., Suwon-si (KR)

(72) Inventors: Hyune Jea LEE, Suwon-si (KR); Sang Soo JEE, Suwon-si (KR); Jung Hoon LEE, Suwon-si (KR); Younhwa KANG, Suwon-si (KR)

(21) Appl. No.: 19/636,188

(22) Filed: Apr. 1, 2026

(30) Foreign Application Priority Data
Apr. 21, 2025 (KR) 10-2025-0051814

(51) Int. Cl. C09G 1/02; C09K 3/14; H10P 52/40

(52) U.S. Cl. CPC C09G 1/02; C09K 3/1436; H10P 52/403

(57) ABSTRACT

Embodiments provides a polishing slurry including a composite of a two-dimensional material and nano-abrasives, and auxiliary particles, where an average size of the auxiliary particles is larger than an average size of the nano-abrasives, and the auxiliary particles have lower hardness than the nano-abrasives, and a method of manufacturing a semiconductor device.

### CROSS-REFERENCE TO RELATED APPLICATION

This U.S. nonprovisional patent application is based on and claims a priority under 35 U.S.C. § 119 to Korean Patent Application No. 10-2025-0051814 filed in the Korean Intellectual Property Office on Apr. 21, 2025, the contents of which are incorporated herein by reference.

### BACKGROUND

### 1. Field

The present disclosure relates to a polishing slurry and a method of manufacturing a semiconductor device.

### 2. Description of the Related Art

Recently, due to the miniaturization of electronic devices and the subsequent miniaturization of integrated circuits, various methods of forming microstructures such as metal wires with a width of several nanometers, contact holes, or shallow trench isolations have been studied.

In forming such microstructures, polishing processes may be performed to make the surface of the microstructures flat and smooth, and chemical mechanical polishing (CMP) may be one of the polishing processes. Chemical mechanical polishing is a process of providing a polishing slurry including abrasives between a semiconductor substrate including an object to be polished and a polishing pad to planarize the surface of the semiconductor substrate.

### SUMMARY

In order to improve a chemical mechanical polishing performance, it may be required to increase the polishing rate such as material removal rate of the object to be polished. However, when abrasives with a relatively large particle size are used to increase the polishing rate, a large amount of scratch defects may occur on the surface of the object to be polished due to the abrasive, and such a large amount of scratch defects may cause defects in the semiconductor device.

An embodiment provides a polishing slurry capable of removing the object to be polished at a high polishing rate while reducing or preventing defects on the surface of the object to be polished.

An embodiment provides a method of manufacturing the semiconductor device using the polishing slurry.

According to an embodiment, a polishing slurry includes a composite of a two-dimensional material and nano-abrasives, and auxiliary particles. An average size of the auxiliary particles is larger than an average size of the nano-abrasives, and the auxiliary particles have lower hardness than the nano-abrasives.

The auxiliary particles may be two-dimensional or three-dimensional particles including organic materials, inorganic materials, organic-inorganic hybrid materials, or a combination thereof, having negative or positive surface charges in the polishing slurry.

The auxiliary particles may include polymer beads having negative or positive surface charges in the polishing slurry.

At the pH of the polishing slurry, the zeta potentials of the composite and the auxiliary particles may each be greater than 0 or the zeta potentials of the composite and the auxiliary particles may each be less than 0.

Mohs hardness of the two-dimensional material and the auxiliary particles may each be 1 to 5.

Hardness of the nano-abrasives may be higher than hardness of the two-dimensional material.

The nano-abrasives may cover at least a portion of the two-dimensional material.

An area of the two-dimensional material covered with the nano-abrasives may be about 30% to 100% of a total area of the two-dimensional material.

A portion of the nano-abrasives may be partially embedded in the two-dimensional material and partially protrude from a surface of the two-dimensional material.

The two-dimensional material may be an inorganic material having a plate-like structure, a layered structure, or a combination thereof, and the nano-abrasives may include an oxide, a nitride, a fluoride, a carbon material, or a combination thereof, having an average size of less than or equal to about 20 nanometers (nm).

The two-dimensional material may include hexagonal boron nitride, graphene, graphene oxide, graphite, transition metal chalcogenide, or a combination thereof, and the nano-abrasives may include silica, ceria, alumina, zirconia, titania, silicon nitride, aluminum nitride, zirconium nitride, titanium nitride, calcium fluoride, selenium fluoride, tellurium fluoride, SiC, diamond, fullerene, derivatives thereof, or a combination thereof.

The composite and the auxiliary particles may each be included in an amount of about 0.01 to 20 weight percentages (wt %) with respect to a total weight of the polishing slurry.

According to an embodiment, a method of manufacturing a semiconductor device includes supplying a polishing slurry on an object to be polished, and performing chemical mechanical polishing on the object to be polished to which the polishing slurry is supplied. The polishing slurry includes a composite of a two-dimensional material and nano-abrasives, and auxiliary particles. An average size of the auxiliary particles is larger than an average size of the nano-abrasives, and the auxiliary particles have lower hardness than the nano-abrasives.

At the pH of the polishing slurry, the zeta potentials of the composite and the auxiliary particles may each be greater than 0 or the zeta potentials of the composite and the auxiliary particles may each be less than 0.

The auxiliary particles may be two-dimensional or three-dimensional particles including organic materials, inorganic materials, organic-inorganic hybrid materials, or a combination thereof, having negative or positive surface charges in the polishing slurry.

The two-dimensional material may be an inorganic material having a plate-like structure, a layered structure, or a combination thereof, and the nano-abrasives may include an oxide, a nitride, a fluoride, a carbon material, or a combination thereof, having an average size of less than or equal to about 20 nm.

The two-dimensional material may include hexagonal boron nitride, graphene, graphene oxide, graphite, transition metal chalcogenide, or a combination thereof, the nano-abrasives may include silica, ceria, alumina, zirconia, titania, silicon nitride, aluminum nitride, zirconium nitride, titanium nitride, calcium fluoride, selenium fluoride, tellurium fluoride, SiC, diamond, fullerene, derivatives thereof, or a combination thereof, and the auxiliary particles may include polymer beads having negative or positive surface charges in the polishing slurry.

The nano-abrasives may cover at least a portion of the two-dimensional material, and an area of the two-dimensional material covered with the nano-abrasives may be about 30% to 100% of a total area of the two-dimensional material.

Hardness of the two-dimensional material and the auxiliary particles may each be lower than hardness of the object to be polished, and hardness of the nano-abrasives may be higher than hardness of the object to be polished.

The object to be polished may include a metal, a dielectric, a semiconductor, a compound semiconductor, an organic-inorganic compound, or a combination thereof.

During chemical mechanical polishing, the object to be polished may be removed at a high polishing rate, and at the same time, defects on the surface of the object to be polished may be effectively reduced or prevented.

### BRIEF DESCRIPTION OF THE DRAWINGS

FIGS. 1 to 4 are cross-sectional views showing an example of a method of manufacturing a semiconductor device according to an embodiment,

FIG. 5 is a schematic view showing chemical mechanical polishing equipment according to an example,

FIG. 6 is a conceptual view showing an example of an electronic device according to an embodiment,

FIG. 7 is a SEM image of the composite obtained in Synthesis Example 1,

FIG. 8 is a SEM image of the composite obtained in Synthesis Example 2, and

FIG. 9 is a graph showing zeta potentials according to pH of the composite obtained in Synthesis Example 1, the auxiliary particles (spherical polystyrene particles), and a mixture thereof.

### DETAILED DESCRIPTION

Example embodiments will hereinafter be described in detail, and may be easily performed by a person having an ordinary skill in the related art. However, this disclosure may be embodied in many different forms and is not to be construed as limited to the exemplary embodiments set forth herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “plate-like structure” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “plate-like” can mean within one or more standard deviations, or within ±10%, 5% or 2% of the stated value of a complete plate structure.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

As used herein, the term ‘combination’ includes a mixture and a stacked structure of two or more.

As used herein, “metal” includes metals and semimetals.

Hereinafter, a polishing slurry according to an embodiment is described.

Polishing slurry may be used to planarize a solid surface, such as the surface of a semiconductor substrate (including a thin film or a layer such as a dielectric layer, a conductive layer such as a metal layer, or a semiconducting layer), or to remove steps on the solid surface in the manufacturing process of a semiconductor device. Polishing slurry may be used in chemical mechanical polishing process.

The polishing slurry according to an embodiment includes a composite of a two-dimensional material and nano-abrasives, auxiliary particles. and a dispersion medium.

The composite of the two-dimensional material and nano-abrasives (hereinafter referred to as a ‘composite’) may be abrasives in which a two-dimensional material and nano-abrasives are combined, and may be included in the polishing slurry to polish an object to be polished.

The two-dimensional material and the nano-abrasives may have a physically combined form, and for example, each two-dimensional material may support or fix the nano-abrasives. The nano-abrasives may be supported or fixed on the two-dimensional material to directly polish the object to be polished, and may be high-hardness abrasives having higher hardness than the object to be polished.

The two-dimensional material may be a planar material extending along two directions crossing each other (for example, an X direction and a Y direction), and for example, a length extending in the X direction and a width extending in the Y direction may be significantly larger than a thickness extending in a Z direction perpendicular to the X direction and the Y direction, respectively. For example, a length extending in an X direction and a width extending in a Y direction may be each independently several tens of nanometers to several tens of micrometers, and a thickness extending in a Z direction may be angstroms to several nanometers.

For example, a longest dimension (e.g., width or length) extending in an XY in-plane direction of the two-dimensional material may be greater than or equal to about 50 nanometers (nm) and less than or equal to about 100 micrometers (μm), and within the range, may be greater than or equal to about 60 nm, greater than or equal to about 70 nm, greater than or equal to about 80 nm, greater than or equal to about 90 nm, greater than or equal to about 100 nm, greater than or equal to about 110 nm, or greater than or equal to about 120 nm, and within the range, may be less than or equal to about 90 μm, less than or equal to about 80 μm, less than or equal to about 70 μm, less than or equal to about 60 μm, or less than or equal to about 50 μm.

For example, an aspect ratio, which is a ratio of a longest dimension (e.g., width or length) extending in an XY in-plane direction to a thickness extending in a Z direction of the two-dimensional material, may be greater than or equal to about 3:1, and within the range, greater than or equal to about 3.5:1, greater than or equal to about 4:1, greater than or equal to about 4.5:1, greater than or equal to about 5:1, greater than or equal to about 5.5:1, greater than or equal to about 6.0:1, greater than or equal to about 6.5:1, greater than or equal to about 7.0:1, greater than or equal to about 7.5:1, greater than or equal to about 8.0:1, greater than or equal to about 8.5:1, greater than or equal to about 9.0:1, greater than or equal to about 9.5:1, or greater than or equal to about 10:1, and within the range, may be less than or equal to about 1000:1, less than or equal to about 950:1, less than or equal to about 900:1, less than or equal to about 850:1, less than or equal to about 800:1, less than or equal to about 750:1, less than or equal to about 700:1, less than or equal to about 650:1, less than or equal to about 600:1, less than or equal to about 550:1, less than or equal to about 500:1, less than or equal to about 450:1, less than or equal to about 400:1, less than or equal to about 350:1, less than or equal to about 300:1, less than or equal to about 250:1, less than or equal to about 200:1, less than or equal to about 150:1, or less than or equal to about 100:1.

By the two-dimensional material having the dimension and/or the aspect ratio within the range, an effective planar structure may be implemented, and accordingly, not only may it be physically combined with the nano-abrasives or effectively fix the nano-abrasives, but also the polishing rate may be increased by increasing a contact area with an object to be polished during chemical mechanical polishing.

The two-dimensional material may be, for example, an inorganic material, and for example, an inorganic material having a plate-like structure, a layered structure, or a combination thereof. The two-dimensional material may include, for example, hexagonal boron nitride (h-BN), graphene, graphene oxide, graphite, transition metal chalcogenides, or a combination thereof, but is not limited thereto.

The hexagonal boron nitride (h-BN) may be soft hexagonal boron nitride having a plate-like structure, and does not exclude the inclusion of boron oxide on a surface of the hexagonal boron nitride.

Graphene or graphene oxide may be a single layer or a layered structure in which a plurality of layers of 2 or more, 3 or more, 4 or more, or 5 or more, and 100 or less, 90 or less, 80 or less, 70 or less, 60 or less, or 50 or less are stacked. Graphene may be obtained by a mechanical or chemical method. For example, as the mechanical method, the mechanical method using an adhesive tape may be used for obtaining thin graphene sheets, and in this case, when the adhesive tapes are attached to both sides of graphite particles and then opened to both sides, the graphite is split in half, and the thin graphene sheets may be obtained by repeating this process. For example, in a chemical method, graphene may be obtained by preparing a substrate on which a graphitization catalyst (e.g., a metal catalyst such as Ni, Co, Fe, or Pt) is formed on at least one surface, contacting a carbon-based material (e.g., a carbon-containing polymer) as a carbon source on the substrate, and then heat-treating under an inert atmosphere or a reducing atmosphere to form graphene on the graphitization catalyst. However, it is not limited to the methods, and graphene may be obtained by various methods.

Graphite may include natural graphite or artificial graphite.

The transition metal chalcogenide may include at least one transition metal and at least one chalcogen element, and for example, may be a transition metal dichalcogenide represented by MX₂. Herein, M may be a metal (e.g., a transition metal), for example, Mo, W, Nb, Ti, Ta, Pt, Pd, Co, Cr, Cu, Ni, Hf, Sn, Re, or a combination thereof, and X is a chalcogen element and may be, for example, S, Se, Te, or a combination thereof. Metal chalcogenide may include, for example, MoS₂, MoSe₂, MoSSe, MoSTe, Mo₍₁₋ₓ₎WₓS₂, Mo₍₁₋ₓ₎WₓSe₂, Mo₍₁₋ₓ₎WₓTe₂, Mo₍₁₋ₓ₎NbₓS₂, Mo₍₁₋ₓ₎NbₓSe₂, Mo₍₁₋ₓ₎TaₓS₂, Mo₍₁₋ₓ₎TaₓSe₂, Mo₍₁₋ₓ₎WₓSSe, MoTe₂, WS₂, WSe₂, WSSe, WTe₂, WSTe, W₍₁₋ₓ₎NbₓS₂, W₍₁₋ₓ₎NbₓSe₂, PtS₂, PtSe₂, PtTe₂, PdSe₂, TaS₂, TaSe₂, Ta₍₁₋ₓ₎WₓS₂, Ta₍₁₋ₓ₎WₓSe₂, HfS₂, HfSe₂, HfTe₂, TiS₂, TiSe₂, TiTe₂, NbS₂, NbSe₂, NbTe₂, SnS₂, SnSe₂, SnTe₂, ReS₂, ReSe₂, ReTe₂ (where 0≤x≤1), or a combination thereof, but is not limited thereto.

The nano-abrasives may be fine abrasives having a size (for example, a particle size) of tens of nanometers or less, and since the nano-abrasives have a higher hardness than the object to be polished, they may polish the object to be polished by contacting the object to be polished.

The nano-abrasives may be, for example, spherical, plate-like, linear, and/or amorphous particles, and the average size of the nano-abrasives may be, for example, less than about 50 nm, and within the range, may be less than or equal to about 40 nm, less than or equal to about 30 nm, less than or equal to about 25 nm, less than or equal to about 20 nm, less than or equal to about 15 nm, less than or equal to about 10 nm, less than or equal to about 7 nm, less than or equal to about 5 nm, less than or equal to about 3 nm, and within the range, may be greater than or equal to about 1 nm and less than about 50 nm, about 1 nm to 40 nm, about 1 nm to 30 nm, about 1 nm to 25 nm, about 1 nm to 20 nm, about 1 nm to 15 nm, about 1 nm to 10 nm, about 1 nm to 7 nm, about 1 nm to 5 nm, or about 1 nm to 3 nm. Herein, the particle size may be the average particle size in the case of spherical particles, and in the case of non-spherical particles, may mean the average of the length of the longest portion (major axis). The particle size may be measured using a particle size analyzer or evaluated from a transmission electron microscope (TEM) image or a scanning electron microscope (SEM) image. Alternatively, the particle size (for example, average particle size) may be obtained by counting the number of particles according to the particle size range using dynamic light scattering (DLS) and calculating therefrom. The average particle size may mean the diameter (D50) of the particle at which the cumulative volume in the particle size distribution is 50 volume percentages (vol %).

The nano-abrasives may include, for example, oxide, nitride, fluoride, carbon material, or a combination thereof, and may be, for example, silica, ceria, alumina, zirconia, titania, silicon nitride, aluminum nitride, zircon nitride, titanium nitride, calcium fluoride, selenium fluoride, tellurium fluoride, SiC, diamond, fullerene, derivatives thereof, or a combination thereof, but is not limited thereto.

The nano-abrasives may be physically bonded to the two-dimensional material. The nano-abrasives and the two-dimensional material may be bonded with a predetermined bonding force, for example, a bonding force of greater than or equal to about 200 nanonewtons (nN), greater than or equal to about 300 nN, greater than or equal to about 400 nN, greater than or equal to about 500 nN, greater than or equal to about 600 nN, greater than or equal to about 700 nN, greater than or equal to about 800 nN, greater than or equal to about 900 nN, or greater than or equal to about 1000 nN. Herein, the bonding force may be obtained by approaching a probe of an end portion of a cantilever of an atomic force microscope (AFM) to the nano-abrasives and measuring a degree of bending of the cantilever by a force between the probe and the nano-abrasives. By having the bonding force in the range between the nano-abrasives and the two-dimensional material, separation of the nano-abrasives from the two-dimensional material in a polishing slurry may be effectively prevented or reduced.

For example, the nano-abrasives may be adsorbed or attached on a surface of the two-dimensional material having a plate-like structure and/or a layered structure. For example, the nano-abrasives may be fixed on the two-dimensional material having a plate-like structure and/or a layered structure, for example, a portion of the nano-abrasives may be partially embedded in the two-dimensional material and partially protrude from a surface of the two-dimensional material. For example, one end of each nano-abrasive of a portion of the nano-abrasives may protrude from one surface of the two-dimensional material, or both ends of each nano-abrasive may protrude from both opposite surfaces of the two-dimensional material.

As such, at least a portion of the two-dimensional material may be covered with the nano-abrasives due to the structure in which the nano-abrasives are adsorbed or attached to or embedded in or protruded from a surface of the two-dimensional material. Most of the nano-abrasives may be bonded or fixed to a plane extending along an XY direction of the two-dimensional material. For example, an area of the two-dimensional material covered with the nano-abrasives may be greater than or equal to about 30% of a total area of the two-dimensional material, and within the range, may be about 30% to 95%, about 30% to 90%, about 30% to 80%, about 30% to 70%, about 30% to 60%, about 30% to 50%, about 35% to 95%, about 35% to 90%, about 35% to 80%, about 35% to 70%, about 35% to 60%, or about 35% to 50%. Herein, the area covered with the nano-abrasives may be measured using a scanning electron microscope (SEM) image and ImageJ (ImageJ 1.54 g) of the composite. Specifically, in the SEM image of the two-dimensional material magnified with a scale bar of 100 nm, a region of 280 pixels×580 pixels is selected, and an area of the selected region is checked. Subsequently, after selecting a region of the nano-abrasives within the selected region in a Freehand selection mode, an area of the nano-abrasives is checked. Subsequently, a percentage of the area of the nano-abrasives with respect to the area of the selected region is calculated. An average is obtained by identically evaluating five different regions on the surface of the two-dimensional material.

As described above, the nano-abrasives in the composite may have a higher hardness than the object to be polished, and thus the nano-abrasives in the composite may polish the object to be polished by contacting the object to be polished. On the other hand, the two-dimensional material in the composite may have a lower hardness than the object to be polished, and thus the two-dimensional material in the composite may support or fix the nano-abrasives and may not directly participate in polishing. Accordingly, the nano-abrasives may have a higher hardness than each of the object to be polished and the two-dimensional material, and the two-dimensional material may have a lower hardness than each of the object to be polished and the nano-abrasives. Herein, the hardness may be evaluated by, for example, Mohs hardness.

The object to be polished may be, for example, a metal, a dielectric, a semiconductor, a compound semiconductor, an organic-inorganic compound, or a combination thereof, and may include, for example, a metal such as aluminum, copper, molybdenum, tungsten, or nickel, an alloy thereof, or a metal oxide or metalloid oxide generated in a chemical mechanical polishing process; an oxide such as silicon oxide or aluminum oxide; a nitride such as silicon nitride, aluminum nitride, titanium nitride, or gallium nitride; a carbide such as silicon carbide; a semiconductor such as silicon or germanium; a compound semiconductor such as InP or GaAs; an organic-inorganic compound such as tetraethyl orthosilicate (TEOS); or a combination thereof, and Mohs hardness of the object to be polished may belong to, for example, 5.0 to 9.0.

Mohs hardness of the nano-abrasives may belong to, for example, 6.0 to 10.0 within a range higher than the object to be polished. The nano-abrasives may effectively polish the object to be polished by having a hardness in the range.

Mohs hardness of the two-dimensional material may be, for example, 1.0 to 5.0 within a range lower than each of the Mohs hardness of the object to be polished and the Mohs hardness of the nano-abrasives, respectively, and may be 1.0 to 4.0, 1.0 to 3.0, or 1.0 to 2.0 within the range. By the two-dimensional material having a hardness in the range, scratch defects may not be generated on the object to be polished when contacting the object to be polished.

A difference in Mohs hardness between the nano-abrasives and the two-dimensional material may be, for example, greater than or equal to 2.0, may be greater than or equal to 3.0, greater than or equal to 4.0, or greater than or equal to 5.0, within the range, and may be 2.0 to 9.0, 3.0 to 8.0, 4.0 to 7.0, or 5.0 to 6.0 within the range. By the nano-abrasives and the two-dimensional material having the difference in Mohs hardness within the range, the object to be polished may be effectively polished by the nano-abrasives and scratch defects may not be generated on the object to be polished by the two-dimensional material when the composite contacts the object to be polished during a chemical mechanical polishing process.

As described above, the composite has a structure in which a plurality of nano-abrasives are fixed to the two-dimensional material having a plate-like structure and/or a layered structure, so that the nano-abrasives fixed to the two-dimensional material may simultaneously participate in polishing, and accordingly, polishing performance (for example, a polishing rate) may be increased compared to when separated nano-abrasives individually participate in polishing, thereby effectively overcoming limits of polishing performance due to a small size of the nano-abrasives. In addition, due to a planar structure of the two-dimensional material, a contact area with the object to be polished may be increased during chemical mechanical polishing, so that the polishing performance may be more effectively increased.

The composite may be obtained by synthesizing the two-dimensional material and the nano-abrasives in a dispersion medium (a dispersion medium for synthesizing the composite). For example, the composite may be obtained by mixing a precursor of the nano-abrasives and the two-dimensional material in the dispersion medium for synthesizing the composite to prepare a mixture and then heat-treating the mixture. For example, the composite may be obtained by respectively preparing a first dispersion obtained by dispersing the precursor for the nano-abrasives in a first dispersion medium for synthesizing the composite and a second dispersion obtained by dispersing the two-dimensional material in a second dispersion medium for synthesizing the composite that is the same as or different from the first dispersion medium, and heat-treating a mixture of the first dispersion and the second dispersion.

The precursor of the nano-abrasives may be, for example, a metal salt, a hydrate thereof, or a combination thereof, and the metal salt may be, for example, an acetate, halide, nitrate, oxalate, or alkoxide, including a metal, or a combination thereof, but is not limited thereto. For example, when the nano-abrasives are ceria, the metal may be cerium and the metal salt may be cerium acetate, cerium acetate hydrate, cerium chloride, cerium chloride hydrate, cerium nitrate, cerium nitrate hydrate, cerium oxalate, cerium oxalate hydrate, ammonium cerium nitrate, cerium isopropoxide, or a combination thereof, but is not limited thereto.

The first and second dispersion medium for synthesizing the composite may include, for example, methanol, ethanol, propanol, isopropanol, methyl cellosolve, ethyl cellosolve, diethylene glycol methyl ether, diethylene glycol ethyl ether, dipropylene glycol methyl ether, toluene, xylene, hexane, heptane, octane, ethyl acetate, butyl acetate, diethylene glycol dimethyl ether, diethylene glycol dimethyl ethyl ether, methyl methoxypropionate, ethyl ethoxypropionate, ethyl lactate, propylene glycol methyl ether acetate, propylene glycol methyl ether, propylene glycol propyl ether, methyl cellosolve acetate, ethyl cellosolve acetate, diethylene glycol methyl acetate, diethylene glycol ethyl acetate, acetone, methyl isobutyl ketone, cyclohexanone, dimethylformamide (DMF), N,N-dimethylacetamide (DMAc), N-methyl-2-pyrrolidone, γ-butyrolactone, diethyl ether, ethylene glycol dimethyl ether, diglyme, tetrahydrofuran, or a combination thereof, but is not limited thereto.

The dispersion (including the first dispersion and the second dispersion) may further include a reducing agent. The reducing agent may be, for example, an amine compound, and may be, for example, a trialkylamine such as trimethylamine, triethylamine, or the like, a triarylamine such as triphenylamine, or a combination thereof, but is not limited thereto.

The heat treatment may be performed at, for example, greater than or equal to about 60 degrees in Celsius (° C), within the range, may be performed at greater than or equal to about 70 °C, greater than or equal to about 80 °C, greater than or equal to about 90 °C, or greater than or equal to about 100 °C, and within the range, may be performed at about 60 °C to 800 °C, about 70 °C to 800 °C, about 80 °C to 800 °C, about 90 °C to 800 °C, about 100 °C to 800 °C, about 60 °C to 600 °C, about 70 °C to 600 °C, about 80 °C to 600 °C, about 90 °C to 600 °C, about 100 °C to 600 °C, about 60 °C to 400 °C, about 70 °C to 400 °C, about 80 °C to 400 °C, about 90 °C to 400 °C, or about 100 °C to 400 °C, but is not limited thereto.

The composite may be included in an amount of about 0.01 to 20 weight percentages (wt %) with respect to a total weight of the polishing slurry, and within the range, may be included in an amount of about 0.01 to 15 wt % or about 0.01 to 10 wt %.

The auxiliary particles may be relatively low hardness soft particles that do not directly participate in polishing. Instead of directly participating in polishing, the auxiliary particles may increase polishing performance, for example, a polishing rate, of the composite by effectively transferring a load applied from a polishing head to the composite during chemical mechanical polishing. For example, the nano-abrasives fixed to the two-dimensional material or protruding from the two-dimensional material may directly contact the object to be polished to perform polishing, and at this time, the auxiliary particles may make the composite in closer contact with the object to be polished by contacting the two-dimensional material to provide a predetermined pressure, thereby increasing the polishing performance, for example, the polishing rate, by increasing the number of the nano-abrasives contacting the object to be polished and/or increasing the pressure applied from the nano-abrasives to the object to be polished.

An average size of the auxiliary particles may be larger than an average size of the nano-abrasives. Accordingly, the auxiliary particles may increase contact area with the composite and effectively transfer a load applied from the polishing head to the composite during chemical mechanical polishing. For example, an average size of the auxiliary particles may be about 5 times or more larger than an average size of the nano-abrasives, and within the range, may be about 10 times or more, about 20 times or more, about 30 times or more, about 50 times or more, about 100 times or more, about 150 times or more, or about 200 times or more larger, and may be about 10,000 times or less, about 8,000 times or less, about 5,000 times or less, or about 1,000 times or less larger.

The auxiliary particles may have a relatively large particle size, and an average size of the auxiliary particles may be, for example, greater than or equal to about 20 nm, and for example, about 20 nm to 50 μm. Within the range, the average size of the auxiliary particles may be about 20 nm to 40 μm, about 20 nm to 30 μm, about 20 nm to 20 μm, about 20 nm to 10 μm, about 20 nm to 5 μm, about 20 nm to 3 μm, about 20 nm to 1 μm, about 30 nm to 50 μm, about 30 nm to 40 μm, about 30 nm to 30 μm, about 30 nm to 20 μm, about 30 nm to 10 μm, about 30 nm to 5 μm, about 30 nm to 3 μm, about 30 nm to 1 μm, about 50 nm to 50 μm, about 50 nm to 40 μm, about 50 nm to 30 μm, about 50 nm to 20 μm, about 50 nm to 10 μm, about 50 nm to 5 μm, about 50 nm to 3 μm, or about 50 nm to 1 μm. Herein, the average size may be an average particle diameter (for example, D50) in the case of a spherical shape and may mean the average of the lengths of the longest portions in the case of a non-spherical shape.

Since the auxiliary particles have a relatively large size as described above, it may be possible to increase contact area with the composite and effectively transfer the load applied from the polishing head to the composite during chemical mechanical polishing as described above, and at the same time, it may be possible to effectively prevent deterioration of polishing performance by reducing or preventing the auxiliary particles from getting stuck in grooves of a polishing pad used during chemical mechanical polishing.

The auxiliary particles may have a relatively low hardness. As described above, since the auxiliary particles may enhance the polishing performance of the composite without substantially participating in polishing, the hardness of the auxiliary particles may be lower than each of the hardness of the object to be polished and the hardness of the nano-abrasives that substantially perform polishing, respectively.

The Mohs hardness of the object to be polished may be 5.0 to 9.0 as described above, and the Mohs hardness of the nano-abrasives may be 6.0 to 10.0 as described above. Mohs hardness of the auxiliary particles may be, for example, 1.0 to 5.0 within a range lower than each of the Mohs hardness of the object to be polished and the Mohs hardness of the nano-abrasives, respectively, and may be 1.0 to 4.0, 1.0 to 3.0, or 1.0 to 2.0, within the range. Since the auxiliary particles have the hardness within the range, damage such as scratches may not be caused to the object to be polished when contacting the object to be polished.

The auxiliary particles may be charged in the polishing slurry, and thus may have negative or positive surface charges. The auxiliary particles may have surface charges of the same sign as the composite, for example, the auxiliary particles may also have positive surface charges when the composite has positive surface charges, and for example, the auxiliary particles may also have negative surface charges when the composite has negative surface charges. By including the auxiliary particles with surface charges of the same sign as the composite in this way, an electrostatic repulsive force may effectively act between the composite and the auxiliary particles, so that aggregation or adsorption between the composite and the auxiliary particles and precipitation resulting therefrom may be effectively prevented or reduced.

The surface charges may be evaluated by a zeta potential. The zeta potential indicates an electrostatic potential of the particle surface at a predetermined pH, and it may be possible to determine a type and an amount of charges on the particle. The zeta potential may be measured using electrophoretic mobility by electrophoresis.

The zeta potential may change according to pH, and at a predetermined pH, for example, a process pH or a polishing slurry pH, the auxiliary particles may secure an electrostatic repulsive force between the composite and the auxiliary particles by having a zeta potential of the same sign as the composite. For example, the process pH or the pH of the polishing slurry may belong to 2.0 to 12.0, and within the range, may belong to a range of 2.0 to 10.0, 2.0 to 8.0, 2.0 to 6.5, 2.0 to 6.0, 3.0 to 6.5, 3.0 to 6.0, 3.5 to 6.5, 3.5 to 6.0 or 3.5 to 5.5. For example, the process pH or the pH of the polishing slurry may belong to 3.0 to 6.0.

For example, at the pH of the polishing slurry, the composite and the auxiliary particles may maintain a zeta potential of the same sign. For example, at the pH of the polishing slurry, the zeta potentials of the composite and the auxiliary particles may each be greater than 0 or each be less than 0. For example, when composite having a zeta potential greater than 0 (i.e., a positive zeta potential) at the pH of the polishing slurry is used, the auxiliary particles having a zeta potential greater than 0 (i.e., a positive zeta potential) at the pH of the polishing slurry may be selected. For example, when a composite having a zeta potential less than 0 (i.e., a negative zeta potential) at the pH of the polishing slurry is used, the auxiliary particles having a zeta potential less than 0 (i.e., a negative zeta potential) at the pH of the polishing slurry may be selected.

For example, the zeta potentials of the composite and the auxiliary particles may each belong to about +5 millivoltages (mV) to +140 mV, and within the range, may belong to about +10 mV to +140 mV, about +10 mV to +120 mV, or about +10 mV to +100 mV. For example, the zeta potentials of the composite and the auxiliary particles may each belong to about −10 mV to −140 mV, and within the range, may belong to about −10 mV to −140 mV, about −10 mV to −120 mV, or about −10 mV to −100 mV.

For example, at the pH of the polishing slurry, the difference between the zeta potential of the auxiliary particles and the zeta potential of the composite may be greater than or equal to about 10 mV, greater than or equal to about 20 mV, or greater than or equal to about 30 mV, and within the range, may be about 10 mV to 100 mV, about 20 mV to 100 mV, about 30 mV to 100 mV, about 10 mV to 80 mV, about 20 mV to 80 mV or about 30 mV to 80 mV. By having the difference of zeta potentials of the auxiliary particles and the composite at the pH of the polishing slurry, a stronger electrostatic repulsive force acts between the auxiliary particles and the composite, so that aggregation or adsorption between the auxiliary particles and the composite and resultant precipitation may be prevented or reduced more effectively.

The auxiliary particles may be two-dimensional or three-dimensional particles including organic materials, inorganic materials, organic-inorganic hybrid materials, or a combination thereof, having negative or positive surface charges in the polishing slurry to satisfy the aforementioned properties.

For example, the auxiliary particles may include an organic material having negative or positive surface charges in the polishing slurry, and may be, for example, polymer beads, which are three-dimensional particles including a polymer. For example, the auxiliary particles (for example, polymer beads) may include polystyrene, styrene-based copolymer, poly(alkyl)(meth)acrylate, acrylic copolymer, polyvinyl chloride, polyacetal, saturated polyester, polyamide, polyimide, polyamide-imide, polycarbonate, phenoxy resin, polyolefin, olefin-based copolymer, polyurea, polyurethane, melamine resin, epoxy resin, derivatives thereof, or a combination thereof, but is not limited thereto. For example, the auxiliary particles (for example, polymer beads) may have a functional group providing negative or positive surface charges on one portion (for example, a main chain or a side chain of the polymer) of the organic material, and the functional group providing the negative surface charges may include, for example, a carboxyl group, a sulfate group, a sulfonate group, a phosphate group, or a combination thereof, and the functional group having the positive surface charges may include, for example, an amine group, a protonated amino group, an ammonium group, or a combination thereof, but is not limited thereto.

The auxiliary particles may be included in an amount of about 0.01 to 20 wt % with respect to a total weight of the polishing slurry, and within the range, may be included in an amount of about 0.01 to 15 wt % or about 0.01 to 10 wt %.

In the polishing slurry, the composite and the auxiliary particles may be included, for example, in a weight ratio of about 1:10 to 10:1. Within the range, the composite and the auxiliary particles may be included, for example, in a weight ratio of about 1:9 to 9:1, about 2:8 to 8:2, about 3:7 to 7:3, about 4:6 to 6:4 or about 5:5. For example, in the polishing slurry, the composite may be included in an amount greater than or equal to that of the auxiliary particles, and for example, the composite and the auxiliary particles may be included in a weight ratio of about 5:5 to 9:1. For example, in the polishing slurry, the composite may be included in an amount less than or equal to that of the auxiliary particles, and for example, the composite and the auxiliary particles may be included in a weight ratio of about 5:5 to 1:9.

In the polishing slurry, the auxiliary particles may be included in a volume greater than or equal to that of the composite, and for example, the auxiliary particles and the composite may be included in a volume ratio of about 1:1 to 30:1. Within the range, the auxiliary particles and the composite may be included in about 1:1 to 25:1, about 1:1 to 23:1, about 1:1 to 20:1, about 1:1 to 15:1, about 1:1 to 10:1, about 1:1 to 5:1 or about 1:1 to 3:1, but is not limited thereto.

By the auxiliary particles and the composite included in the weight ratio and/or volume ratio in the polishing slurry, the auxiliary particles may effectively contact the composite to effectively transfer a load applied from a polishing head to the composite, so that polishing performance (for example, a polishing rate) may be further improved.

The polishing slurry may further include an oxidizing agent. The oxidizing agent may oxidize an object to be polished, and for example, when applying the polishing slurry to the object to be polished including a metal or a semimetal, a surface of the object to be polished may be oxidized to form a metal oxide or a semimetal oxide. The object to be polished (for example, a metal oxide or a metalloid oxide) oxidized by the oxidizing agent may have a relatively lower hardness or be more brittle than the metal or the metalloid, and may be more effectively removed due to a difference in mechanical strength between the object to be polished and the oxidized object to be polished.

The oxidizing agent is not limited as long as it may oxidize the object to be polished, and for example, may include hydrogen peroxide, peracetic acid, percarbonates, urea peroxide, perchloride acid, persulfates, iron(III)nitrate, hydrates thereof, or a combination thereof.

The oxidizing agent may be included in an amount of less than or equal to about 5 wt % with respect to a total weight of the polishing slurry, and within the range, may be included in an amount of about 0.001 wt % to 5 wt %, 0.001 wt % to 4 wt %, 0.001 wt % to 3 wt %, 0.001 wt % to 2 wt %, 0.001 wt % to 1 wt %, or 0.001 wt % to 0.5 wt %.

The polishing slurry may further include an additive. The additive may include, for example, a chelating agent (oxidation regulator), a surfactant, a dispersant, a pH adjuster, a corrosion inhibitor, a reaction catalyst, or a combination thereof.

The chelating agent (oxidation regulator) may be, for example, phosphoric acid, nitric acid, citric acid, malonic acid, salts thereof, or a combination thereof, but is not limited thereto.

The surfactant may be an ionic or non-ionic surfactant, for example, a copolymer of ethylene oxide, a copolymer of propylene oxide, an amine compound, or a combination thereof, but is not limited thereto.

The dispersant may promote dispersion of the composite and the auxiliary particles, and for example, may include a water-soluble monomer, a water-soluble oligomer, a water-soluble polymer, a metal salt, or a combination thereof. A weight average molecular weight of the water-soluble polymer may be, for example, less than or equal to about 10,000, for example, less than or equal to about 5,000, or for example, less than or equal to about 3,000. The metal salt may be, for example, a copper salt, a nickel salt, a cobalt salt, a manganese salt, a tantalum salt, a ruthenium salt, or a combination thereof. The dispersant may be selected from, for example, poly(meth)acrylic acid, poly(meth)acrylic maleic acid, polyacrylonitrile-co-butadiene-acrylic acid, carboxylic acid, sulfonic ester, sulfonic acid, phosphoric ester, cellulose, diol, salts thereof, or a combination thereof, but is not limited thereto.

The pH adjuster may adjust the pH of the polishing slurry, and for example, may be an inorganic acid, an organic acid, salts thereof, or a combination thereof. The inorganic acid may include, for example, nitric acid, hydrochloric acid, phosphoric acid, sulfuric acid, hydrofluoric acid, hydrobromic acid, iodic acid, potassium hydroxide, sodium hydroxide, ammonium hydroxide, or salts thereof, and the organic acid may include, for example, formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glutaric acid, glutamic acid, glycolic acid, lactic acid, aspartic acid, tartaric acid, or salts thereof, but is not limited thereto.

The corrosion inhibitor may effectively prevent or reduce corrosion and/or over-etching of the object to be polished or the oxide of the object to be polished (oxidized by the oxidizing agent) during and/or after the polishing process, and for example, may include leucine, lysine, methionine, valine, serine, cysteine, cystine, arginine, asparagine, aspartic acid, alanine, ornithine, isoleucine, threonine, tyrosine, glutamine, glutamic acid, glycine, histidine, phenylalanine, proline, urea, betaine, or a combination thereof, but is not limited thereto.

The reaction catalyst may promote an oxidation reaction of the object to be polished through decomposition of the oxidizing agent. The reaction catalyst may be, for example, a metal ion compound capable of effectively generating radicals, and for example, may be a catalyst used in a Fenton reaction or a Fenton-like reaction. The reaction catalyst may include, for example, a cation including an iron (Fe) ion, a chromium (Cr) ion, a manganese (Mn) ion, a cobalt (Co) ion, a cerium (Ce) ion, a potassium (K) ion, a silver (Ag) ion, a copper (Cu) ion, a molybdenum (Mo) ion, a niobium (Nb) ion, a nickel (Ni) ion, an osmium (Os) ion, a lead (Pd) ion, a tin (Sn) ion, a titanium (Ti) ion, a vanadium (V) ion, or a combination thereof, and an anion including a nitrate, a sulfate, a fluoride, a chloride, a bromide, an iodide, a fluorate, a chlorate, a bromate, an iodate, a perchlorate, a perbromate, a periodate, a cyanide salt, an oxalate, a citrate, an acetate, an acetyl acetonate, a gluconate, or a combination thereof, but is not limited thereto. For example, the reaction catalyst may be an iron ion catalyst, and for example, may include iron (II) nitrate, iron (III) nitrate, iron (II) sulfate, iron (III) sulfate, iron (II) oxalate, iron (III) oxalate, or a combination thereof, but is not limited thereto.

Each component of the additive may be independently included in a trace amount of, for example, about 1 ppm to 100,000 ppm, but is not limited thereto.

The polishing slurry may further include a dispersion medium capable of dissolving and/or dispersing the above-described components. The dispersion medium may include, for example, water and may include, for example, distilled water and/or deionized water. The dispersion medium may be included in a balance amount excluding solids such as the composite, the auxiliary particles, the oxidizing agent, and various additives.

A pH of the polishing slurry may belong to 2.0 to 12.0, and within the range, may belong to a range of 2.0 to 10.0, 2.0 to 8.0, 2.0 to 6.5, 2.0 to 6.0, 3.0 to 6.5, 3.0 to 6.0, 3.5 to 6.5, 3.5 to 6.0, or 3.5 to 5.5.

The polishing slurry may be applied to various objects to be polished and perform chemical mechanical polishing on a surface of the objects to be polished, and the object to be polished may be, for example, a metal, a dielectric, a semiconductor, a compound semiconductor, an organic-inorganic compound, or a combination thereof, and may include, for example, a metal such as aluminum, copper, molybdenum, tungsten, or nickel, an alloy thereof, or a metal oxide or semimetal oxide formed in a chemical mechanical polishing process; an oxide such as silicon oxide or aluminum oxide; a nitride such as silicon nitride, aluminum nitride, titanium nitride, or gallium nitride; a carbide such as silicon carbide; a semiconductor such as silicon or germanium; a compound semiconductor such as InP or GaAs; an organic-inorganic compound such as tetraethyl orthosilicate (TEOS); or a combination thereof.

For example, the polishing slurry may be applied when forming a structure, for example, may be applied to a polishing process of a conductive layer (metal layer) such as metal wiring or a polishing process of a dielectric layer such as shallow trench isolation (STI). For example, the polishing slurry may be used to polish a conductive layer (metal layer) such as metal wiring in a semiconductor substrate, and for example, may be used to polish a metal layer such as tungsten, molybdenum, aluminum, copper, nickel, or an alloy thereof.

Hereinafter, an example of a method of manufacturing a semiconductor device using the aforementioned polishing slurry will be described. The semiconductor device may include at least one fine structure (for example, a trench, wiring, a dielectric, a semiconductor, or a combination thereof, having a width of less than about 100 nm).

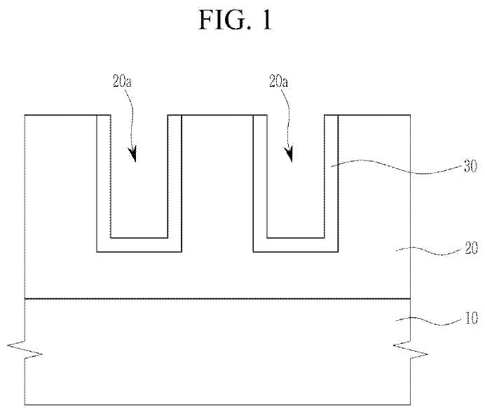

FIGS. 1 to 4 are cross-sectional views showing an example of a method of manufacturing a semiconductor device according to an embodiment.

Referring to FIG. 1, a dielectric layer 20 is formed on a semiconductor substrate 10. The dielectric layer 20 may include an oxide, a nitride, and/or an oxynitride. Subsequently, the dielectric layer 20 is etched to form an opening 20a. The opening may be a trench. A width of the trench 20a may be less than about 50 nm, and within the range, may be greater than or equal to about 1 nm and less than about 50 nm, about 1 nm to 40 nm, about 1 nm to 30 nm, about 1 nm to 20 nm, about 1 nm to 15 nm, about 1 nm to 10 nm, or about 1 nm to 8 nm. Subsequently, a barrier layer 30 is formed on the inside wall of the opening 20a. The barrier layer 30 may include, for example, Ti, Ta, TiN, and/or TaN, but is not limited thereto.

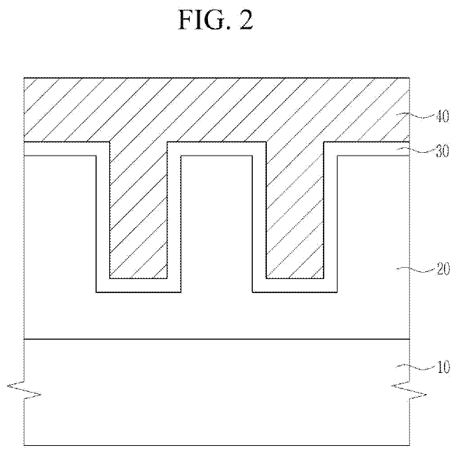

Referring to FIG. 2, inside and top of the opening 20a are filled or coated with a metal to form a conductive layer 40. The conductive layer 40 may include, for example, a metal such as molybdenum, tungsten, aluminum, copper, nickel, alloys thereof, or combinations thereof, but is not limited thereto.

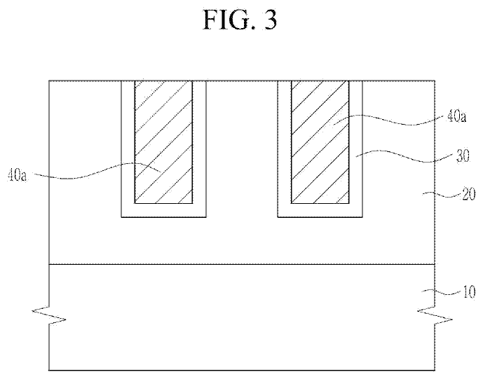

Referring to FIG. 3, the surface of the conductive layer 40 may be planarized to substantially match the surface of the dielectric layer 20 to form an embedded conductive pattern 40a. The planarization may be performed by chemical mechanical polishing using chemical mechanical polishing equipment, and the polishing slurry may be used. The will be described later. For example, when the barrier layer 30 is a Ta layer and the conductive layer 40 is a molybdenum (Mo)-containing layer, the higher the polishing selectivity of Ta to Mo in the polishing slurry, the more desirable, and for example, the higher it is than about 50:1, the more desirable.

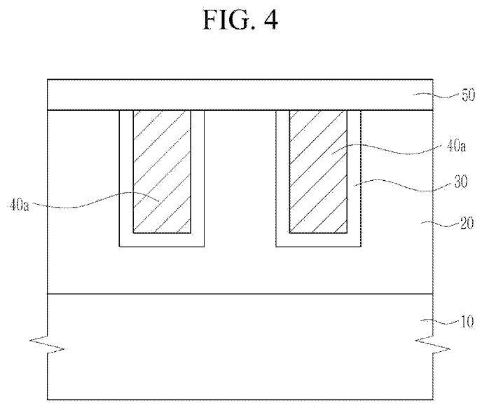

Referring to FIG. 4, a capping layer 50 is formed on the embedded conductive pattern 40a and the dielectric layer 20. The capping layer 50 may include SiN and/or SiC, but is not limited thereto.

Hereinafter, the planarization for forming the embedded conductive pattern 40a is described. The planarization may be performed by chemical mechanical polishing using chemical mechanical polishing equipment.

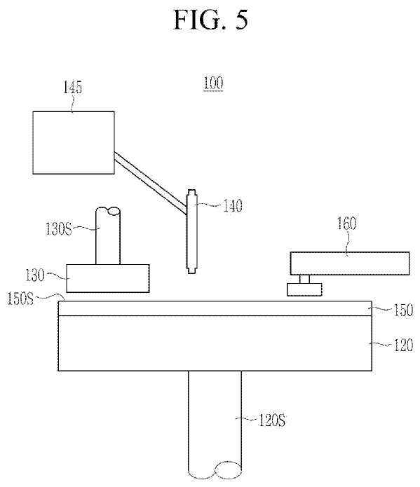

FIG. 5 is a schematic view showing chemical mechanical polishing equipment according to an example.

Referring to FIG. 5, a CMP equipment 100 according to an example may include, for example, a lower base (not shown); a platen 120 rotatably provided on an upper surface of the lower base; a polishing head 130; a polishing pad 150 on the platen 120; a pad conditioner 160; and at least one polishing slurry supply device 140 disposed adjacent to the polishing pad 150 to supply polishing slurry to the polishing pad 150.

The platen 120 may be provided rotatable on the surface of the lower base. For example, the platen 120 may receive rotational power from a motor (not shown) disposed in the lower base, and accordingly may rotate in a certain direction, such as clockwise or counterclockwise, by a rotation axis 120S perpendicular to the surface of the platen 120.

The polishing head 130 may be disposed on the platen 120 and may hold a body to be polished. The body to be polished may be a semiconductor substrate 10, such as a wafer. The polishing head 130 may include a rotating shaft 130S that rotates the body to be polished. When performing polishing, the rotation direction of the polishing head 130 may be opposite to the rotation direction of the platen 120.

The polishing pad 150 may be disposed on the platen 120 so as to be supported by the platen 120. The polishing pad 150 may rotate together with the platen 120. The polishing pad 150 may have a roughly formed polishing surface 150S. This polishing surface 150S may mechanically polish the surface of the semiconductor substrate 10 by directly contacting the semiconductor substrate 10. The polishing pad 150 may be made of a porous material with a plurality of micro spaces, and the plurality of micro spaces may accommodate polishing slurry. The polishing surface 150S of the polishing pad 150 may include a surface that directly contacts the body to be polished and a predetermined depth therefrom, and the predetermined depth may be about 10% to about 100%, about 20% to about 100%, about 30% to about 100%, about 40% to about 100%, or about 50% to about 100% of the thickness of the polishing pad 150. The polishing surface 150S of the polishing pad 150 may be flat, for example. The polishing surface 150S of the polishing pad 150 may have, for example, protrusions or grooves.

A pad conditioner 160 may be adjacent to the polishing pad 150 and may maintain the state of the polishing surface so that the surface of the semiconductor substrate 10 may be effectively polished while the polishing process is performed.

The polishing slurry supply device 140 may be adjacent to the polishing pad 150 and may supply polishing slurry from the polishing slurry tank 145 and supply the polishing slurry to the polishing pad 150. The polishing slurry supply device 140 may include a nozzle capable of supplying polishing slurry onto the polishing pad 150 during the polishing process. The polishing slurry supply device 140 may supply the polishing slurry.

Chemical mechanical polishing may be performed, for example, by disposing a semiconductor substrate 10 and a polishing pad 150 so as to face each other, supplying the polishing slurry between the semiconductor substrate 10 and the polishing pad 150 from a polishing slurry supply device 140, and performing polishing by contacting the polishing pad 150 with the surface of the semiconductor substrate 10.

For example, the supplying of the polishing slurry may be supplied at a rate of, for example, about 10 milliliters per minute (ml/min) to about 300 ml/min.

The performing chemical mechanical polishing may include contacting the surface of the semiconductor substrate 10 (object to be polished) and the polishing pad 150, and in the contacting the polishing pad 150 and the object to be polished, the composites in the polishing slurry may be arranged in a direction substantially parallel to the surface of the polishing pad 150, and the nano-abrasives in the composites may polish the object to be polished by directly contacting the object to be polished. In the performing of chemical mechanical polishing, the polishing head 130 and the platen 120 may rotate in different directions, and polishing may be performed by mechanical friction between the surface of the semiconductor substrate 10 (object to be polished) held by the polishing head 130 and the polishing pad 150 positioned on the platen 120. A pressure of about 1 pound per square inch (psi) to about 5 psi may be applied during the polishing.

Although a method of manufacturing a semiconductor device according to an example is described above, it is not limited thereto, and may be applied to semiconductor devices with various structures.

The semiconductor device manufactured as described above may be included in an integrated circuit device. The integrated circuit device may be, for example, a DRAM or logic device, but is not limited thereto. The integrated circuit device may include, for example, a unit device including a transistor, a capacitor, a diode, a resistor, or a combination thereof. For example, the transistor may have various structures, and may be, for example, a FinFET, GAAFET, MBCFET, CFET, or VFET, but is not limited thereto.

The integrated circuit device may be included in various electronic devices. The electronic device may include, for example, a mobile device, computer, a laptop, tablet PC, smart watch, sensor, digital camera, electronic book, network device, vehicle navigation, Internet of Things (IoT) device, Internet of Everything (IoE) device, drone, door lock, safe, automated teller machine (ATM), security device, medical device, display device, or automotive electronic component, but is not limited thereto

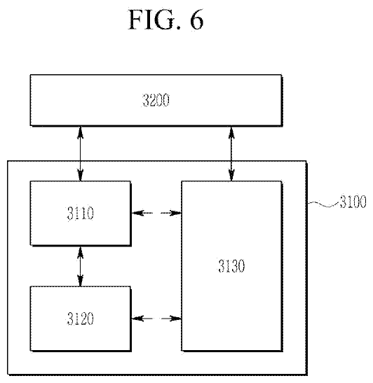

FIG. 6 is a conceptual view showing an example of an electronic device according to one embodiment.

Referring to FIG. 6, the electronic device 3100 according to an embodiment may include a memory unit 3110, an arithmetic logic unit 3120, and a control unit 3130, and these may be electrically connected. For example, the memory unit 3110, the arithmetic logic unit 3120, and the control unit 3130 may be implemented as one integrated circuit device (semiconductor chip), and, for example, may be monolithically integrated on a single substrate and implemented as a single integrated circuit device (semiconductor chip). The memory unit 3110, the arithmetic logic unit 3120, and the control unit 3130 may each independently include a transistor, a capacitor, a diode, a resistor, or a combination thereof. The electronic device 3100 may be connected to one or more input/output devices 3200.

Hereinafter, the embodiments are illustrated in more detail with reference to examples. However, these examples are exemplary, and the scope of claims is not limited thereto.

### Preparation of Composite

### Synthesis Example 1

0.315 g of cerium(III) nitrate hexahydrate (CeN₃O₉·6H₂O, Sigma-Aldrich Co.) is dissolved in 65 ml of ethanol, and 5 ml of deionized water is added thereto. After confirming that the cerium(III) nitrate hexahydrate is completely dissolved to prepare a solution, 0.5 g of a plate-like hexagonal boron nitride powder (h-BN, width (w)<100 nm, thickness (t)<20 nm, Mohs hardness: 2.0), which is a two-dimensional material, is mixed with the solution, and the resulting mixture is treated with ultrasonic waves for 10 minutes. While vigorously stirring the ultrasonically treated mixture, a solution in which 0.280 g of trimethylamine (Sigma-Aldrich Co.) is dissolved in 10 ml of NMP (N-methyl-2-pyrrolidone) is added dropwise at a rate of 1.0 ml/min using a syringe and stirred at room temperature (about 24 °C) for 24 hours to obtain a product. Subsequently, the product is washed three times with ethanol and dried in an oven at 85 °C for at least 4 hours. Subsequently, the dried product is placed in a furnace and calcined at 600 °C for 30 minutes to prepare a composite in which ceria (D50<10 nm, Mohs hardness: 7.5 to 8.0) is loaded on hexagonal boron nitride (Mohs hardness: 2.0) in a protruding form.

### Synthesis Example 2

0.315 g of cerium(III) nitrate hexahydrate (CeN₃O₉·6H₂O, Sigma-Aldrich Co.) is dissolved in 65 ml of ethanol, and 5 ml of deionized water is added thereto. After confirming that the cerium(III) nitrate hexahydrate is completely dissolved to prepare a solution, 0.5 g of the composite obtained in Synthesis Example 1 is mixed with the solution, and the resulting mixture is treated with ultrasonic waves for 10 minutes. While vigorously stirring the ultrasonically treated mixture, a solution in which 0.280 g of trimethylamine (Sigma-Aldrich Co.) is dissolved in 10 ml of NMP is added dropwise at a rate of 1.0 ml/min using a syringe and stirred at room temperature (about 24 °C) for 24 hours to obtain a product. Subsequently, the product is washed three times with ethanol and dried in an oven at 85 °C for at least 4 hours. Subsequently, the dried product is placed in a furnace and calcined at 600 °C for 30 minutes to prepare a composite in which ceria (D50<10 nm, Mohs hardness: 7.5 to 8.0) is loaded on hexagonal boron nitride (Mohs hardness: 2.0) in a protruding form.

### Evaluation I

A surface images of the composites obtained in the Synthesis Examples are confirmed.

The surface images of the composites are confirmed using a scanning electron microscope (SEM).

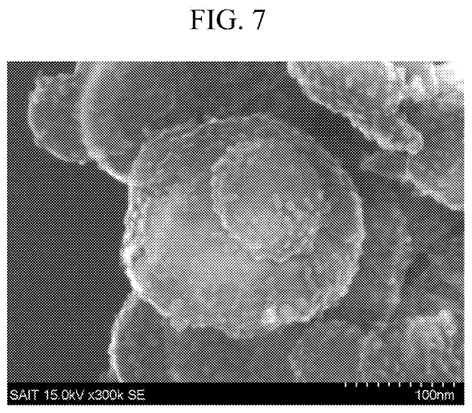

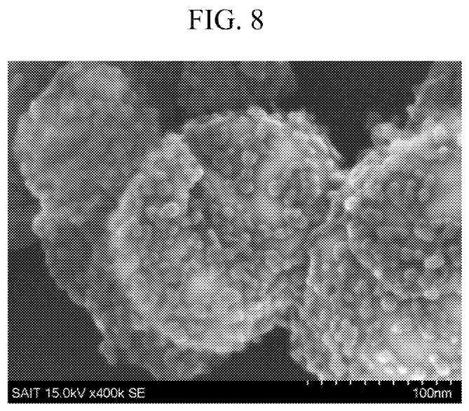

FIG. 7 is a SEM image of the composite obtained in Synthesis Example 1, and FIG. 8 is a SEM image of the composite obtained in Synthesis Example 2.

Referring to FIGS. 7 and 8, it may be confirmed that the composites obtained in the Synthesis Examples include a two-dimensional material (h-BN) and nano-abrasives (ceria) covering at least a portion of the two-dimensional material. In addition, it may be confirmed that the composite obtained in Synthesis Example 2, which is obtained by applying a ceria precursor once more to the composite obtained in Synthesis Example 1, has more nano-abrasives (ceria) covering the surface of the two-dimensional material (h-BN) compared to the composite obtained in Synthesis Example 1.

### Evaluation II

From FIGS. 7 and 8, a ratio of an area covered with the nano-abrasives to the total surface area of the two-dimensional material is evaluated.

The area covered with the nano-abrasives may be measured using a SEM photograph of the composite and Image J. Specifically, in a SEM photograph of the two-dimensional material magnified with a scale bar of 100 nm, a region of a width of 280 pixels and a height of 580 pixels is selected, and an area of the selected region is checked. Subsequently, after selecting a region of the nano-abrasives within the selected region in a Freehand selection mode, an area of the nano-abrasives is checked. Subsequently, a percentage of the area of the nano-abrasives with respect to the area of the selected region is calculated. An average is obtained by identically evaluating five different regions on the surface of the two-dimensional material.

The results are shown in Table 1.

TABLE 1

| | Area covered with |
|---|---|
| | nano-abrasives (%) |
| Synthesis Example 1 | 32.5 |
| Synthesis Example 2 | 44.2 |

Referring to Table 1, it may be confirmed that, in the composites obtained in Synthesis Examples, an area of the two-dimensional material covered with the nano-abrasives among the total surface area of the two-dimensional material is greater than about 30%, and it may be confirmed that the composite obtained in Synthesis Example 2, in which a larger amount of ceria precursor is used, has a larger area of the two-dimensional material covered with the nano-abrasives among the total surface area of the two-dimensional material.

### Preparation of Polishing Slurry

### Preparation Example 1

0.5 wt % of the composite obtained in Synthesis Example 1, 0.125 wt % of auxiliary particles (spherical polystyrene particles, D50: 50 nm, Mohs hardness: 1.5 to 2.5), 0.01 wt % of glutamic acid, a trace amount of nitric acid, a trace amount of ammonia water, and the balance of deionized water are mixed to prepare a polishing slurry of pH 5.0.

### Preparation Example 2

0.5 wt % of the composite obtained in Synthesis Example 1, 0.125 wt % of auxiliary particles (spherical polystyrene particles, D50: 200 nm, Mohs hardness: 1.5 to 2.5), 0.01 wt % of glutamic acid, a trace amount of nitric acid, a trace amount of ammonia water, and the balance of deionized water are mixed to prepare a polishing slurry of pH 5.0.

### Preparation Example 3

0.5 wt % of the composite obtained in Synthesis Example 2, 0.125 wt % of auxiliary particles (spherical polystyrene particles, D50: 200 nm, Mohs hardness: 1.5 to 2.5), 0.01 wt % of glutamic acid, a trace amount of nitric acid, a trace amount of ammonia water, and the balance of deionized water are mixed to prepare a polishing slurry of pH 5.0.

### Reference Preparation Example 1

0.5 wt % of a plate-shaped hexagonal boron nitride powder (h-BN, Sigma-Aldrich, width (w)<100 nm, thickness (t)<20 nm) which is a two-dimensional material, 0.01 wt % of glutamic acid, a trace amount of nitric acid, a trace amount of ammonia water, and the balance of deionized water are mixed to prepare a polishing slurry of pH 5.0.

### Reference Preparation Example 2

0.125 wt % of auxiliary particles (spherical polystyrene particles, D50: 50 nm, Mohs hardness: 1.5 to 2.5), 0.01 wt % of glutamic acid, a trace amount of nitric acid, a trace amount of ammonia water, and the balance of deionized water are mixed to prepare a polishing slurry of pH 5.0.

### Reference Preparation Example 3

0.125 wt % of auxiliary particles (spherical polystyrene particles, D50: 200 nm, Mohs hardness: 1.5 to 2.5), 0.01 wt % of glutamic acid, a trace amount of nitric acid, a trace amount of ammonia water, and the balance of deionized water are mixed to prepare a polishing slurry of pH 5.0.

### Reference Preparation Example 4

0.5 wt % of the composite obtained in Synthesis Example 1, 0.01 wt % of glutamic acid, a trace amount of nitric acid, a trace amount of ammonia water, and the balance of deionized water are mixed to prepare a polishing slurry of pH 5.0.

### Evaluation III

The zeta potentials according to pH of the composites obtained in Synthesis Examples, the auxiliary particles (spherical polystyrene particles), and a mixture thereof are evaluated.

The zeta potentials according to pH are measured using a NanoPartica particle analyzer SZ-100VZ (Horiba), and dispersions prepared by respectively dispersing the composite obtained in Synthesis Examples, the auxiliary particles (spherical polystyrene particles), and a mixture thereof in deionized water are prepared, and the zeta potentials are measured while changing the pH in the range of 3.9 to 5.0.

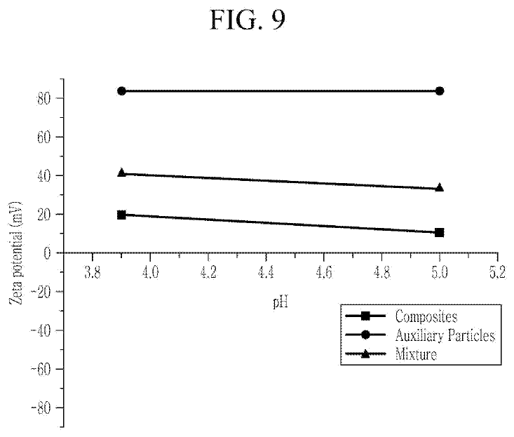

The results are shown in Table 2 and FIG. 9.

FIG. 9 is a graph showing zeta potentials according to pH of the composite obtained in Synthesis Example 1, the auxiliary particles (spherical polystyrene particles), and a mixture thereof.

TABLE 2

| | Zeta potential (mV) |
|---|---|
| | (@ pH 5.0) |
| Composite | 10.6 |
| Auxiliary particles | 83.1 |
| Mixture of composite and | |
| auxiliary particles | 33.1 |

Referring to Table 2 and FIG. 9, it may be confirmed that the composite obtained in Synthesis Example 1, the auxiliary particles (spherical polystyrene particles), and a mixture thereof each exhibit a positive zeta potential in a predetermined pH range (for example, about 3.9 to 5.0).

From this, it may be expected that a high electrostatic repulsive force acts between the composite and the auxiliary particles having a zeta potential of the same sign, so that the dispersion stability of the polishing slurry is high.

### Chemical Mechanical Polishing

Chemical mechanical polishing (CMP) is performed under the following conditions.
(1) CMP equipment: GNP POLI-400L (G&P Technology, Inc.)
(2) Object to be polished: 40 mm×40 mm silicon wafer coupon on which a silicon oxide layer is formed
(3) Polishing head rotation speed: 91 rpm
(4) Polishing platen rotation speed: 90 rpm
(5) Applied pressure: 5.0 psi
(6) Initial temperature: 24 °C
(7) Polishing pad: IT-2000 (KPX Chemical Co.)
(8) Polishing slurry: polishing slurry according to Preparation Examples and Reference Preparation Examples (45 °C)
(9) Polishing slurry supply flow rate: 150 ml/min
(10) Polishing time: 1 minute

### Evaluation IV

The material removal rate (MRR) for the silicon oxide layer is evaluated in chemical mechanical polishing using the polishing slurries according to Preparation Examples and Reference Preparation Examples.

The material removal rate (MRR) is calculated using the following Calculation Equation 1.

Material removal rate (MRR, Å/min)=(thickness of the silicon oxide layer before polishing (Å)−thickness of the silicon oxide layer after polishing (Å))/polishing time (min) [Calculation Equation 1]

In Calculation Equation 1, the thickness of the silicon oxide layer is an average value obtained by measuring the thickness of the center portion of the silicon oxide layer five times using film thickness equipment (ST5030-SL, K-MAC).

The results are shown in Table 3.

TABLE 3

| | Polishing rate |
|---|---|
| | (Å/min) |
| Preparation Example 1 | 246 |
| Preparation Example 2 | 322 |
| Preparation Example 3 | 475 |
| Reference Preparation Example 1 | 3 |
| Reference Preparation Example 2 | 3 |
| Reference Preparation Example 3 | 3 |
| Reference Preparation Example 4 | 124 |

Referring to Table 3, it may be confirmed that the polishing slurries according to Preparation Examples may increase the material removal rate for an object to be polished compared with the polishing slurries according to Reference Preparation Examples. On the other hand, it may be confirmed that polishing is not substantially performed by the plate-shaped hexagonal boron nitride powder (h-BN) (Reference Preparation Example 1), which is a two-dimensional material, alone or the polystyrene particles (Reference Preparation Examples 2 and 3), which are the auxiliary particles, alone.

### Evaluation V

The surface roughness of the silicon oxide layer is evaluated in chemical mechanical polishing according to Examples and Reference Examples.

The surface roughness is evaluated from an average value of flatness of an area of 600 μm×600 μm using an atomic force microscope (AFM) (NX20, Park system Co.).

The results are shown in Table 4.

TABLE 4

| | Rₐ (nm) | Rₚ (nm) |
|---|---|---|
| Preparation Example 1 | 0.070 | 0.0873 |
| Preparation Example 2 | 0.067 | 0.0850 |
| Preparation Example 3 | 0.060 | 0.078 |
| Reference Preparation Example 4 | 0.130 | 0.199 |

* Rₐ: average roughness
* Rₚ: maximum profile peak height

Referring to Table 4, it may be confirmed that performing chemical mechanical polishing using the polishing slurries according to Preparation Examples results in having relatively low surface roughness and high flatness compared with performing chemical mechanical polishing using the polishing slurries according to Reference Preparation Examples.

From this, it may be confirmed that the polishing slurries according to Preparation Examples may reduce or prevent scratch defects on the surface of an object to be polished compared with the polishing slurries according to Reference Preparation Examples.

While this disclosure has been described in connection with what is presently considered to be practical example embodiments, it is to be understood that the inventive concept is not limited to the disclosed embodiments. On the contrary, it is intended to cover various modifications and equivalent arrangements included within the spirit and scope of the appended claims.

What is claimed is:

1. A polishing slurry comprising:
a composite of a two-dimensional material and nano-abrasives, and
auxiliary particles, wherein an average size of the auxiliary particles is larger than an average size of the nano-abrasives, and the auxiliary particles have lower hardness than the nano-abrasives.

2. The polishing slurry of claim 1, wherein the auxiliary particles are two-dimensional or three-dimensional particles including organic materials, inorganic materials, organic-inorganic hybrid materials, or a combination thereof, having negative or positive surface charges in the polishing slurry.

3. The polishing slurry of claim 1, wherein the auxiliary particles include polymer beads having negative or positive surface charges in the polishing slurry.

4. The polishing slurry of claim 1, wherein zeta potentials of the composite and the auxiliary particles are each greater than 0 or the zeta potentials of the composite and the auxiliary particles are each less than 0 at the pH of the polishing slurry.

5. The polishing slurry of claim 1, wherein Mohs hardnesses of the two-dimensional material and the auxiliary particles are each 1 to 5.

6. The polishing slurry of claim 1, wherein the hardness of the nano-abrasives is higher than a hardness of the two-dimensional material.

7. The polishing slurry of claim 1, wherein at least a portion of the two-dimensional material is covered with the nano-abrasives.

8. The polishing slurry of claim 7, wherein an area of the two-dimensional material covered with the nano-abrasives is about 30% to 100% of a total area of the two-dimensional material.

9. The polishing slurry of claim 1, wherein a portion of the nano-abrasives is partially embedded in the two-dimensional material and partially protrudes from a surface of the two-dimensional material.

10. The polishing slurry of claim 1, wherein
the two-dimensional material is an inorganic material having a plate-like structure, a layered structure, or a combination thereof, and
the nano-abrasives comprise an oxide, a nitride, a fluoride, a carbon material, or a combination thereof, having an average size of less than or equal to 20 nanometers (nm).

11. The polishing slurry of claim 10, wherein
the two-dimensional material comprises hexagonal boron nitride, graphene, graphene oxide, graphite, transition metal chalcogenide, or a combination thereof, and
the nano-abrasives comprise silica, ceria, alumina, zirconia, titania, silicon nitride, aluminum nitride, zirconium nitride, titanium nitride, calcium fluoride, selenium fluoride, tellurium fluoride, SiC, diamond, fullerene, derivatives thereof, or a combination thereof.

12. The polishing slurry of claim 1, wherein the composite and the auxiliary particles are each included in 0.01 to 20 weight percentages (wt %) with respect to a total weight of the polishing slurry.

13. A method of manufacturing a semiconductor device comprising:
supplying a polishing slurry on an object to be polished; and
performing chemical mechanical polishing on the object to be polished to which the polishing slurry is supplied,
wherein the polishing slurry comprises
a composite of a two-dimensional material and nano-abrasives, and
auxiliary particles,
wherein an average size of the auxiliary particles is larger than an average size of the nano-abrasives, and the auxiliary particles have lower hardness than the nano-abrasives.

14. The method of claim 13, wherein zeta potentials of the composite and the auxiliary particles are each greater than 0 or the zeta potentials of the composite and the auxiliary particles are each less than 0 at the pH of the polishing slurry.

15. The method of claim 13, wherein the auxiliary particles are two-dimensional or three-dimensional particles including organic materials, inorganic materials, organic-inorganic hybrid materials, or a combination thereof, having negative or positive surface charges in the polishing slurry.

16. The method of claim 13, wherein
the two-dimensional material is an inorganic material having a plate-like structure, a layered structure, or a combination thereof, and
the nano-abrasives comprise an oxide, a nitride, a fluoride, a carbon material, or a combination thereof, having an average size of less than or equal to about 20 nm.

17. The method of claim 16, wherein
the two-dimensional material comprises hexagonal boron nitride, graphene, graphene oxide, graphite, transition metal chalcogenide, or a combination thereof,
the nano-abrasives comprise silica, ceria, alumina, zirconia, titania, silicon nitride, aluminum nitride, zirconium nitride, titanium nitride, calcium fluoride, selenium fluoride, tellurium fluoride, SiC, diamond, fullerene, derivatives thereof, or a combination thereof, and
the auxiliary particles comprise polymer beads having negative or positive surface charges in the polishing slurry.

18. The method of claim 13, wherein
at least a portion of the two-dimensional material is covered with the nano-abrasives, and
an area of the two-dimensional material covered with the nano-abrasives is about 30% to 100% of a total area of the two-dimensional material.

19. The method of claim 13, wherein
a hardness of the two-dimensional material and the hardness of the auxiliary particles are each lower than a hardness of the object to be polished, and
the hardness of the nano-abrasives is higher than the hardness of the object to be polished.

20. The method of claim 13, wherein the object to be polished comprises metal, dielectric, semiconductor, compound semiconductor, organic-inorganic compound, or a combination thereof.
